(19) United States
(12) Patent Application Publication
(10) Pub. No.: US 2013/0228741 A1
(43) Pub. Date: Sep. 5, 2013

(54) LIGHT EMITTING DIODE

(71) Applicant: Yi-Keng Fu, Hsinchu County (TW)

(72) Inventor: Yi-Keng Fu, Hsinchu County (TW)

(73) Assignee: INDUSTRIAL TECHNOLOGY RESEARCH INSTITUTE, Hsinchu (TW)

(21) Appl. No.: 13/469,070

(22) Filed: May 10, 2012

(30) Foreign Application Priority Data
Mar. 1, 2012 (TW) 101106753

(51) Int. Cl. H01L 33/04

(52) U.S. Cl. 257/13; 257/E33.008

(57) ABSTRACT

A light emitting diode including a sapphire substrate, a n-type semiconductor layer, an active layer, a p-type semiconductor layer, a first and a second electrode is provided. The n-type semiconductor layer is disposed on the sapphire substrate. The active layer has an active region with a defect density greater than or equal to 2×10⁷/cm³. The active layer is disposed between the n-type and p-type semiconductor layers. The wavelength of light emitted by the active layer is λ, and 222 nm≦λ≦405 nm. The active layer includes i quantum barrier layers and (i−1) quantum wells, each quantum well is disposed between any two quantum barrier layers, and i≧2. N-type dopant is doped in at least k layers of the i quantum barrier layers, wherein k is a natural number and k≧1, when i even, k≧i/2, and when i is odd, k≧(i−1)/2.

### CROSS-REFERENCE TO RELATED APPLICATION

This application claims the priority benefit of Taiwan application serial no. 101106753, filed on Mar. 1, 2012. The entirety of the above-mentioned patent application is hereby incorporated by reference herein and made a part of this specification.

### BACKGROUND

1. Technical Field

The technical field relates to a light emitting diode (LED), and more particularly to an LED capable of enhancing the luminous efficiency.

2. Related Art

A light emitting diode (LED) is a semiconductor device constituted mainly by group III-V compound semiconductor materials, for example. Since such semiconductor materials have a characteristic of converting electricity into light, when a current is applied to the semiconductor materials, electrons therein would be combined with holes and release excessive energy in a form of light, thereby achieving an effect of luminosity.

Generally speaking, since the lattice mismatch between gallium nitride (GaN) and sapphire substrate is approximately 16%, a large quantity of defects are generated at the lattice interface, and thus causing a drastic decay in the light emitting intensity. The amount of defects is unavoidable during the growth process of LED. However, when the emitted wavelength of light from the LED is 450 nm, it is conventionally known that lattice stress is released around the defects and forms self-assembled indium-riched regions. Therefore, when carriers move to the defects, the carriers are likely to capture by the self-assembled indium-riched regions, thus forming the so-called localized effect. Since the quantum confinement effect of the self-assembled indium-riched regions is capable of increasing the carrier recombination efficiency, therefore, even though the GaN LED is limited by the high defect density, a certain degree of luminous efficiency is still maintained at the 450 nm wavelength of light.

However, when the emission wavelength of the LED gradually shifts from blue to the ultraviolet wavelengths of light, due to the concentration of indium decreasing gradually in the active layer, the self-assembled indium-riched regions are also correspondingly lessened. Consequently, the carriers in the LED are likely to move to the defect areas, thereby drastically decreasing the luminous efficiency of the LED at the ultraviolet wavelengths. Therefore, many people try to enhance the luminous efficiency for the ultraviolet LEDs.

### SUMMARY

A light emitting diode (LED) is provided in the disclosure. By having the layer number of the quantum barrier layers doped with n-type dopants satisfying a specific proportion, the luminous efficiency of the LED at the 222 nm-405 nm wavelength range can be enhanced.

Another LED is provided in the disclosure. By having the lowest doping concentration at the quantum barrier layer doped with n-type dopants that is closest to the p-type semiconductor, the luminous efficiency of the LED at the 222 nm-405 nm wavelength range can be enhanced.

An LED is provided in the disclosure. By having the doping concentrations of the quantum barrier layers doped with n-type dopants satisfying a specific relationship, the luminous efficiency of the LED at the 222 nm-405 nm wavelength range can be enhanced.

The disclosure provides an LED, including a substrate, a n-type semiconductor layer, an active layer, a p-type semiconductor layer, a first electrode, and a second electrode. The n-type semiconductor layer is disposed on the substrate. The active layer has an active region with a defect density DD, in which DD≧2×10⁷/cm³. The active layer is disposed on a portion of the n-type semiconductor layer, and a wavelength of light emitted by the active layer is 222 nm≦λ≦405 nm. The active layer includes i quantum barrier layers and (i−1) quantum wells. Each of the quantum wells is disposed between any two quantum barrier layers, and i is a natural number greater than or equal to 2, in which a n-type dopant is doped in at least k layers of the quantum barrier layers, k being a natural number greater than or equal to 1, when i is an even number, k≧i/2, and when i is an odd number, k≧(i−1)/2. The p-type semiconductor layer is disposed on the active layer. The first electrode is disposed on a portion of the n-type semiconductor layer, and the second electrode is disposed on a portion of the p-type semiconductor layer.

The disclosure provides another LED, including a substrate, a n-type semiconductor layer, an active layer, a p-type semiconductor layer, a first electrode, and a second electrode. The n-type semiconductor layer is disposed on the substrate. The active layer has an active region with a defect density DD, in which DD≧2×10⁷/cm³. The active layer is disposed on a portion of the n-type semiconductor layer, and a wavelength λ of light emitted by the active layer is 222 nm≦λ≦405 nm. The active layer includes i quantum barrier layers and (i−1) quantum wells. Each of the quantum wells is disposed between any two quantum barrier layers, and i is a natural number greater than or equal to 2, in which a n-type dopant is doped in at least k layers of the quantum barrier layers, k being a natural number greater than or equal to 1, when i is an even number, k≧i/2, and when i is an odd number, k≧(i−1)/2. The p-type semiconductor layer is disposed on the active layer, and a doping concentration of the quantum barrier layer in the k quantum barrier layers nearest to the p-type semiconductor layer is less than or equal to the doping concentration of the other quantum barrier layers in the k quantum barrier layers. The first electrode is disposed on a portion of the n-type semiconductor layer, and the second electrode is disposed on a portion of the p-type semiconductor layer.

The disclosure provides another LED, including a substrate, a n-type semiconductor layer, an active layer, a p-type semiconductor layer, a first electrode, and a second electrode. The active layer has an active region with a defect density DD, in which DD≧2×10⁷/cm³. The n-type semiconductor layer is disposed on the substrate. The active layer is disposed on a portion of the n-type semiconductor layer, and a wavelength λ of light emitted by the active layer is 222 nm≦λ≦405 nm. The active layer includes i quantum barrier layers and (i−1) quantum wells. Each of the quantum wells is disposed between any two quantum barrier layers, and i is a natural number greater than or equal to 2, in which a n-type dopant is doped in at least k layers of the quantum barrier layers, k being a natural number greater than or equal to 1, when i is an even number, k≧i/2, when i is an odd number, k≧(i−1)/2, and a doping concentration of the k quantum barrier layers is from 5×10¹⁷/cm³ to 1×10¹⁹/cm³. The p-type semiconductor layer is disposed on the active layer. The first electrode is disposed on a portion of the n-type semiconductor layer, and the second electrode is disposed on a portion of the p-type semiconductor layer.

In summary, in the LED according to the embodiments of the disclosure, by having a number of quantum barrier layers of the active layer doped with n-type dopants, in which the layer number of the doped quantum barrier layers satisfies a specific relationship, or by having the lowest doping concentration at the quantum barrier layer doped with n-type dopants closest to the p-type semiconductor, or by having the doping concentrations of the quantum barrier layers doped with n-type dopants satisfying a specific relationship, the n-type dopants can compensate for the effect which defects have on the carriers. Accordingly, the carrier recombination rate of the LED can be enhanced. Therefore, by employing any one of the afore-described techniques, the luminous efficiency of the LED in the disclosure can be drastically increased at the 222 nm-405 nm wavelength range.

Several exemplary embodiments accompanied with figures are described in detail below to further describe the disclosure in details.

### BRIEF DESCRIPTION OF THE DRAWINGS

The accompanying drawings constituting a part of this specification are incorporated herein to provide a further understanding of the disclosure. Here, the drawings illustrate embodiments of the disclosure and, together with the description, serve to explain the principles of the disclosure.

FIG. 1 is a schematic cross-sectional view of an LED according to an exemplary embodiment.

FIG. 2A is a schematic cross-sectional view of a single quantum well active layer in an LED according to an exemplary embodiment.

FIG. 2B is a schematic cross-sectional view of a multi-quantum well active layer in an LED according to an exemplary embodiment.

FIG. 3 is an enlarged schematic cross-sectional view of an active layer in an LED according to an exemplary embodiment.

FIG. 4A depicts a comparative example of LEDs according to an exemplary embodiment.

FIG. 4B depicts a comparative example of LEDs according to an exemplary embodiment.

FIGS. 5A-5D respectively represents simulation diagrams of the LED electron concentration when the number of doped quantum barrier layers in FIG. 3 is adjusted.

FIGS. 6A-6D respectively represents simulation diagrams of the LED hole concentration when the number of doped quantum barrier layers in FIG. 3 is adjusted.

FIGS. 7A-7D respectively represents simulation diagrams of the LED electron-hole recombination rate when the number of doped quantum barrier layers in FIG. 3 is adjusted.

FIGS. 8A-8D respectively represents simulation diagrams of the LED non-radiative recombination rate when the number of doped quantum barrier layers in FIG. 3 is adjusted.

FIG. 9A is a relational diagram depicting the impact different number of doped layers in the quantum barrier layers of an LED has on the current-output power curve.

FIG. 9B is a relational diagram depicting the impact different number of doped layers in the quantum barrier layers of an LED has on the current-voltage curve.

FIG. 10A is a relational diagram depicting the impact different doping concentrations in the quantum barrier layers of an LED has on the current-output power curve.

FIG. 10B is a relational diagram depicting the impact different doping concentrations in the quantum barrier layers of an LED has on the current-voltage curve.

### DESCRIPTION OF EMBODIMENTS

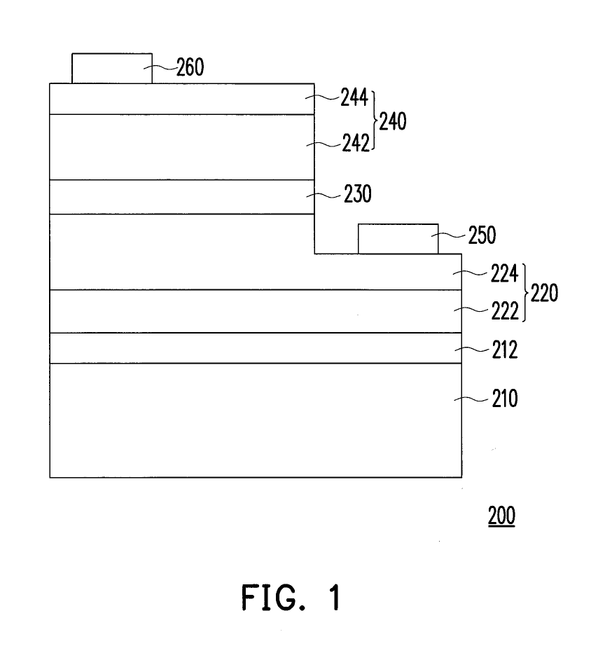

FIG. 1 is a schematic cross-sectional view of an LED according to an exemplary embodiment.

Referring to FIG. 1, an LED 200 includes a substrate 210, a n-type semiconductor layer 220, an active layer 230, a p-type semiconductor layer 240, a first electrode 250, and a second electrode 260. The substrate 210 is, for example, a sapphire substrate. Specifically, the stacking layers of a nitride semiconductor capping layer 212 (e.g. un-doped GaN), a n-type semiconductor layer 220, an active layer 230, the active layer 230 and the p-type semiconductor layer 240 are formed in sequence on a surface of the sapphire substrate 210. The active layer 230 is disposed between the n-type semiconductor layer 220 and the p-type semiconductor layer 240. The n-type semiconductor layer 220 may include the stacking layers of a first n-type doped GaN layer 222 and a second n-type doped GaN layer 224 disposed sequentially on the nitride semiconductor capping layer 212. The p-type semiconductor layer 240 may include the stacking layers of a first p-type doped GaN layer 242 and a second p-type doped GaN layer 244 disposed sequentially on the active layer 230. Moreover, a difference between the first n-type doped GaN layer 222 and the second n-type GaN layer 224, or a difference between the first p-type doped GaN layer 242 and the second p-type doped GaN layer 244 may be in thickness or in doping concentration. Furthermore, a material of the n-type semiconductor layer 220 and the p-type semiconductor layer 240 may be AlGaN, for example. According to requirements in practice, people skilled in the art may select the thickness, doping concentration, and the aluminum concentration for growth of the nitride semiconductor capping layer 212, the first n/p-type doped GaN layers 222 and 242, the second n/p-type doped GaN layers 224 and 244 grown, although the disclosure is not limited thereto.

Specifically, as shown in FIG. 1, the nitride semiconductor capping layer 212 (e.g. un-doped GaN), the first n-type doped GaN layer 222 and the second n-type doped GaN layer 224, the active layer 230, the first p-type doped AlGaN layer 242 and the second p-type doped GaN layer 244 are formed in sequence on the sapphire substrate 210. Moreover, the first electrode 250 and the second electrode 260 are respectively formed on a portion of the second n-type doped GaN layer 224 and the second p-type doped GaN layer 244, so that the first electrode 250 is electrically connected to the n-type semiconductor layer 220, and the second electrode 260 is electrically connected to the p-type semiconductor layer 240. It should be appreciated that, a nitride buffer layer may also be added between the sapphire substrate and the n-type semiconductor, although the disclosure is not limited thereto.

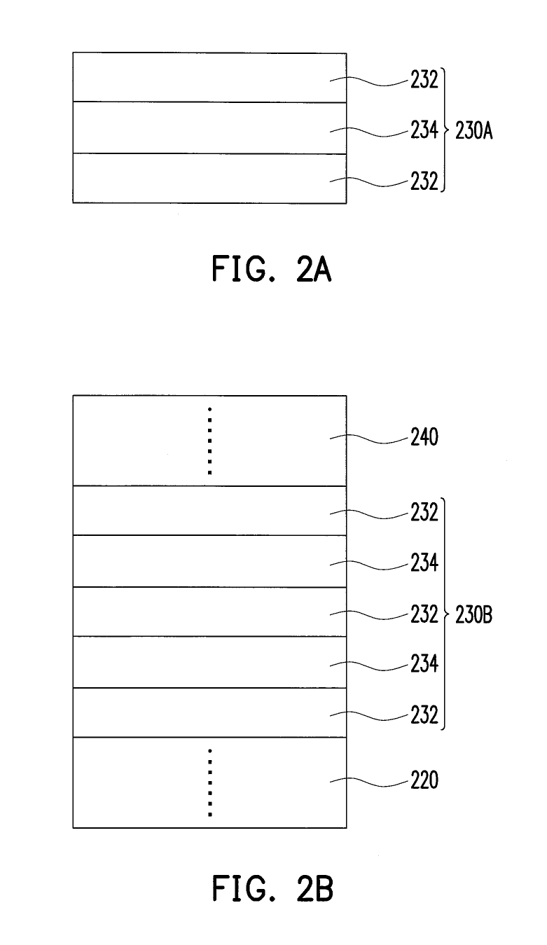

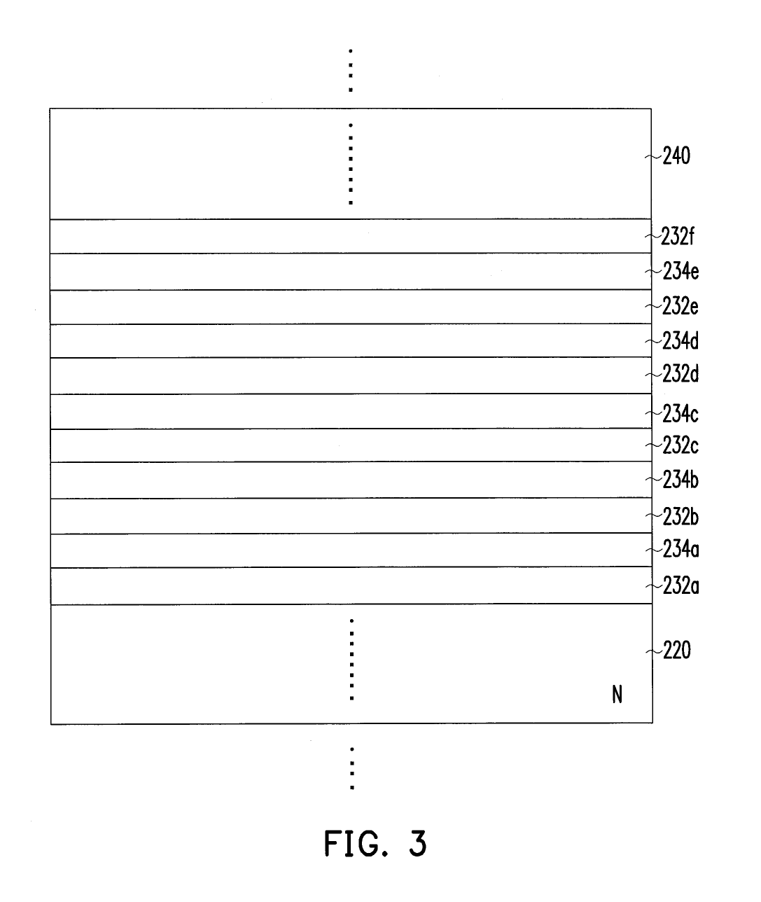

The composition of the active layer 230 may be as shown in FIGS. 2A and 2B, with a single quantum well active layer 230A or a multi-quantum well active layer 230B. FIG. 2A is a schematic cross-sectional view of a single quantum well active layer in an LED according to an exemplary embodiment, and FIG. 2B is a schematic cross-sectional view of a multi-quantum well active layer in an LED according to an exemplary embodiment. Generally speaking, the active layer includes i quantum barrier layers and (i−1) quantum wells. Moreover, each of the quantum wells is disposed between any two quantum barrier layers, and i is a natural number greater than or equal to 2. For example, as shown in FIG. 2A, the single quantum well active layer 230A may be formed by two quantum barrier layers 232 and a quantum well 234 sandwiched therebetween, constituting quantum barrier layer 232/quantum well 234/quantum barrier layer 232. Taking the LED 200 with an emitted wavelength of 222 nm-405 nm as an example, a material of the quantum barrier layers 232 may be AlₓIn_{y}Ga_{1-x-y}N, in which 0≦x≦1, 0≦y≦0.3, and x+y<1. Moreover, a material of the quantum well 234 may be AlₘInₙGa₁₋ₘ₋ₙN, in which 0≦m<1, 0≦n≦0.5, m+n≦1, x>m, and n≧y. According to requirements in practice such as different emitted wavelengths, people skilled in the art may select the concentrations of m and n, or x and y for growth, although the disclosure is not limited thereto.

On the other hand, the composition of the active layer may be as shown by the multi-quantum well active layer 230B in FIG. 2B. As shown in FIG. 2B, the multi-quantum well active layer 230B may be formed by at least two pairs of stacking quantum barrier layers 232 and the quantum wells 234, for example as depicted by the repeating three pairs of the stacking quantum barrier layer 232/quantum well 234.

It should be noted that, in the LED 200 of the disclosure, a n-type dopant doping process is performed on the quantum barrier layers 232 in the active layer 230, so as to adjust a layer number of doped quantum barrier layers 232 in the quantum barrier layers 232, a doping concentration in the quantum barrier layers 232, and a doping concentration distribution in different doped quantum barrier layers 232 in order to enhance the luminous efficiency of the LED 200 at the 222 nm-405 nm wavelengths. Specifically, although GaN growth techniques are limited by a certain amount of defect density inherent in fabrication, however, even when the active layer 230 in the LED 200 has a defect density on the order of 10⁷/cm³, the effect of the defect density in the active region on the carriers can be lowered by intentionally doping n-type dopants through adjusting the layer number and the doping concentrations of the doped quantum barrier layers 232, thereby enhancing the luminous efficiency. Particularly, the enhancement effect is especially pronounced for the emitted light from the active layer 230 having a wavelength range from 222 nm to 405 nm.

The effects of the LED 200 in the disclosure are further illustrated with support from the experimental results described below. In the embodiments hereafter, silicon is used as the n-type dopant as an exemplary scope for implementation, although people skilled in the art may also use other elements in the same group IVA as silicon to implement the embodiments in the disclosure by substituting the silicon.

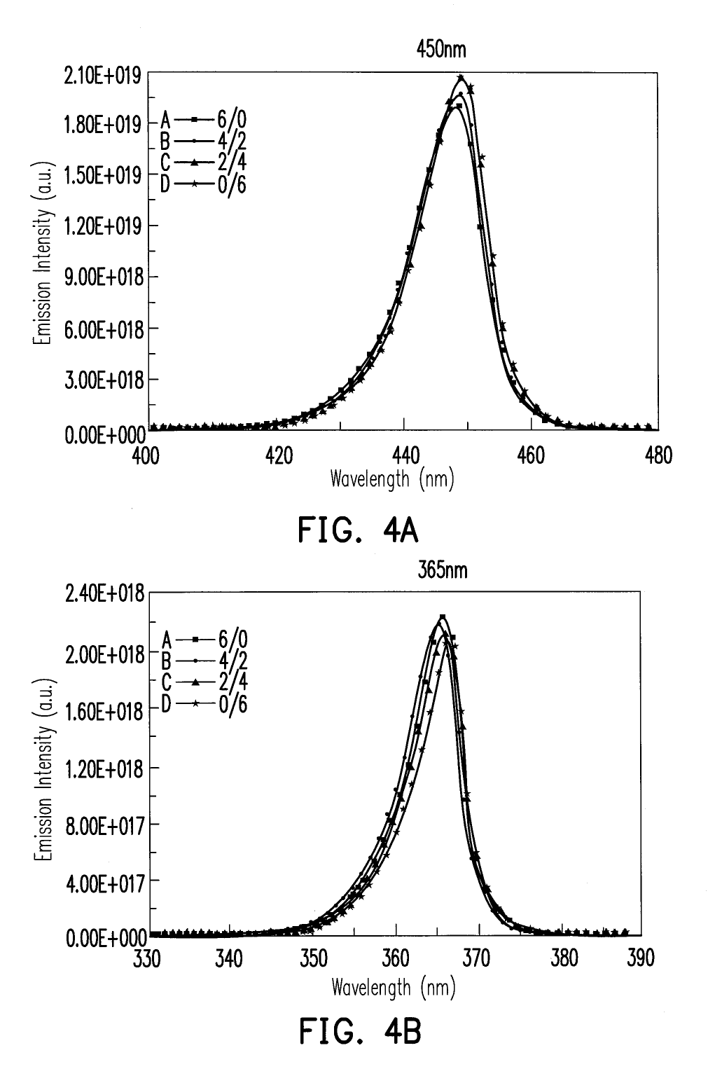

FIG. 3 is an enlarged schematic cross-sectional view of an active layer in an LED. As shown in FIG. 3, the active layer in the present embodiment includes six quantum barrier layers and five quantum wells, and each quantum well is sandwiched between any two quantum barrier layers. Counting from the n-type semiconductor side, the quantum barrier layers are, sequentially, 232a, 232b, 232c, 232d, 232e, and 232f. The quantum wells are, sequentially, 234a, 234b, 234c, 234d, and 234e, counting from the n-type semiconductor side.

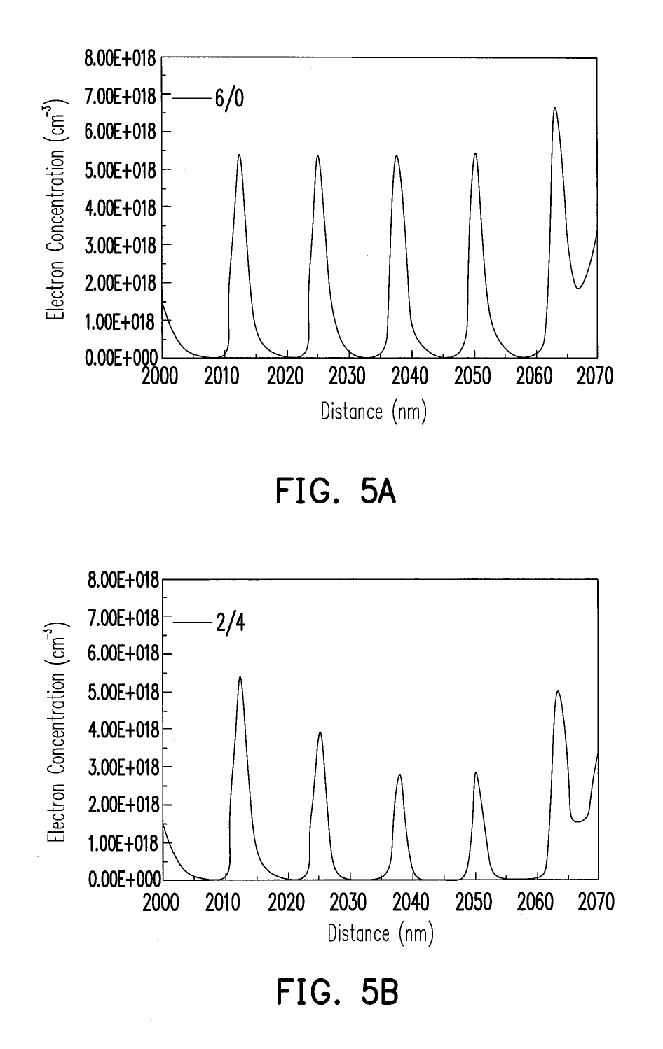

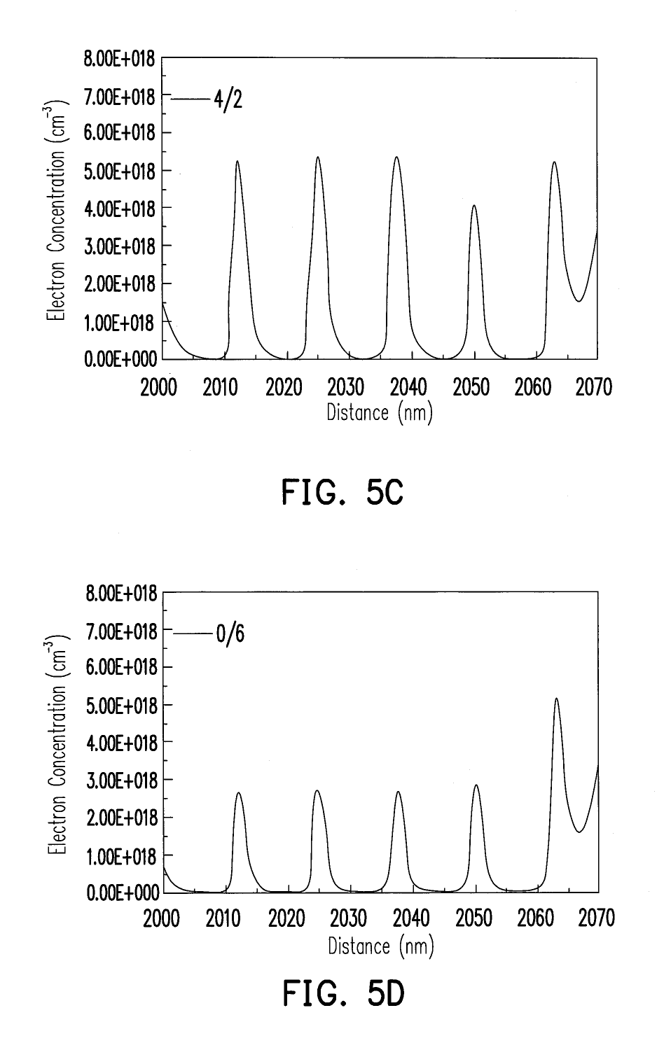

FIG. 4A is an optical simulation diagram of an LED comparison example according to an exemplary embodiment, and FIG. 4B is an optical simulation diagram of an LED according to an exemplary embodiment, in which the defect density in FIGS. 4A and 4B is set as 1×10⁸/cm³. Please refer first to FIG. 4A, FIG. 4A is a relational diagram between adjustments to the layer number of doped quantum barrier layers in the quantum barrier layers 232a-232f and the emission intensities of an emission wavelength around 450 nm for an LED according to an exemplary embodiment. Referring both to FIGS. 3 and 4A, the horizontal axis represents the emission wavelength (unit: nm), and the vertical axis represents the emission intensity (unit: a.u.). Moreover, the numerals before and after the slanted line of the different lines A, B, C, and D respectively represents the layer numbers of doped/un-doped quantum barrier layers in the quantum barrier layers 232a-232f. The layer numbers of the doped layers are counted from the n-type semiconductor layer 220 side. For example, 6/0 in the line A represents all six of the quantum barrier layers 232a-232f are doped. 4/2 in the line B represents four quantum barrier layers 232a-232d near the n-type semiconductor layer 220 side are doped quantum barrier layers, and two layers are un-doped quantum barrier layers 232e-232f. 2/4 in the line C represents two quantum barrier layers 232a-232b near the n-type semiconductor layer 220 side are doped quantum barrier layers, and four layers are un-doped quantum barrier layers 232c-232f. On the other hand, 0/6 in the line D represents all six of the quantum barrier layers 232a-232f are un-doped. As shown in FIG. 4A, the results show that increasing the layer number of doped quantum barrier layers instead decreases the luminous efficiency of the LED around 450 nm.

By contrast, when the layer number of doped quantum barrier layers is increased, the emission intensity of the LED at the 222 nm-405 nm wavelength range can be effectively enhanced. Specifically, FIG. 4B is a relational diagram between adjustments to the layer number of doped quantum barrier layers in the quantum barrier layers and the emission intensities of an emission wavelength around 365 nm. In FIG. 4B, the definitions of the horizontal axis, the vertical axis, and the lines are similar to FIG. 4A, but FIG. 4B represents an emission wavelength range of 222 nm-405 nm having a main peak of around 365 nm. As shown in FIG. 4B, the results show that increasing the layer number of doped quantum barrier layers 232 promotes the enhancement of the luminous efficiency of the LED at the 222 nm-405 nm wavelength range.

When the emission wavelength from the LED is near 450 nm, it can inferred from the results presented in FIGS. 4A and 4B that, due to the comparatively strong localized effect in the quantum wells, the carriers are not easily influenced by the defect density. Therefore, doping the quantum barrier layers with n-type dopants cannot effectively enhance the emission intensity near 450 nm. On the other hand, too much doping results in the carrier overflow phenomenon and thus lowers the emission intensity, as shown in FIG. 4A. However, for the LED having an emission wavelength around 365 nm, the effect of doping the quantum barrier layers with n-type dopants has a completely inverse effect from the LED emitting near 450 nm.

Specifically, as shown in FIG. 4B, when the emission wavelength range of the LED near the main peak of 365 nm is 222 nm-405 nm, due to the weakened localized effect in the quantum wells, the carriers experience comparatively stronger influence from the defect density, and therefore doping the available quantum barrier layers with n-type dopants (e.g. Si) helps compensate for the effect of the defect density on the carriers. In other words, the n-type dopants can also provide radiative recombination for the electrons, thereby effectively enhancing the luminous efficiency of the LED at the 222 nm-405 nm emission wavelength range. The n-type dopants referred here in the disclosure may be dopants from group IV capable of replacing the group III elements and provided from an external source. As shown in FIG. 4B, the emission intensity of the emission wavelength range from 222 nm-405 nm increases as the layer number of the doped quantum barrier layers increases. The enhancement effect of the luminous efficiency is especially pronounced when a layer number k of the doped quantum barrier layers and a total number i of the quantum barrier layers satisfy the following formula: when i is an even number, k≧i/2; and when i is an odd number, k≧=(i−1)/2.

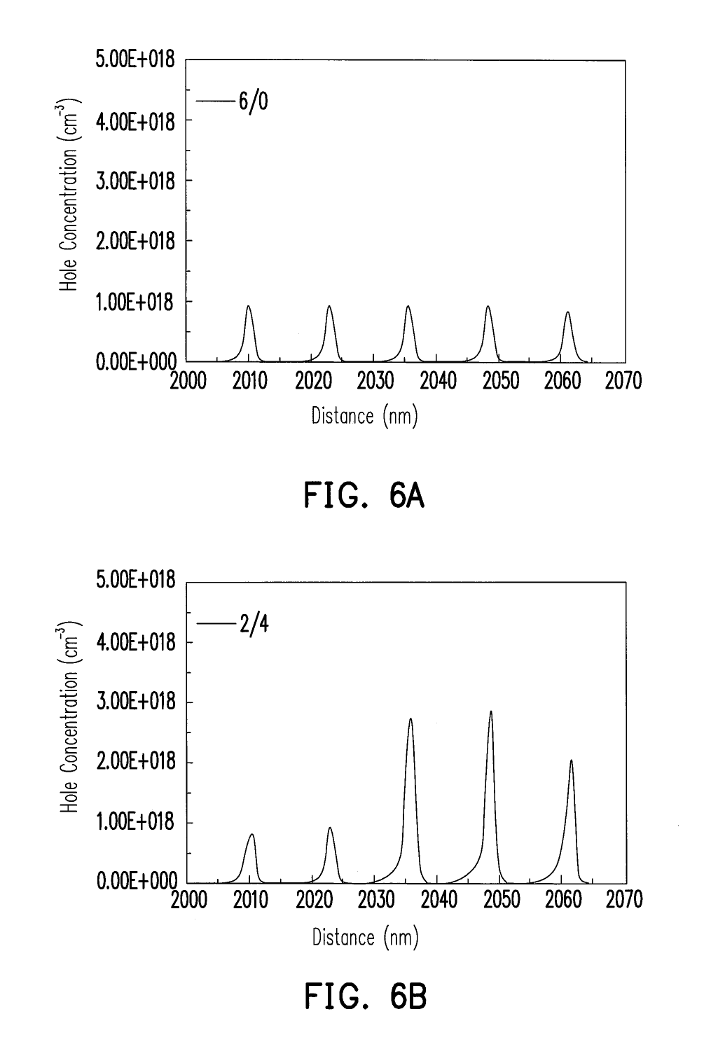

In order to further verify the deductions arrived at above, FIGS. 5A-8D respectively represents for an LED with an emission wavelength range of 222 nm-405 nm, simulation diagrams of the LED electron concentration, hole concentration, electron-hole recombination rate, and non-radiative recombination rate when the number of doped quantum barrier layers 232 in FIG. 3 is adjusted. In FIGS. 5A-8D, the horizontal axis represents a distance from a substrate surface (unit: nm), and the numerals before and after the slanted line in FIGS. 5A-8D respectively represents the layer numbers of doped quantum barrier layers and un-doped quantum barrier layers, with definitions thereof being the same as the lines A-D in FIGS. 4A and 4B, and so further elaboration is omitted.

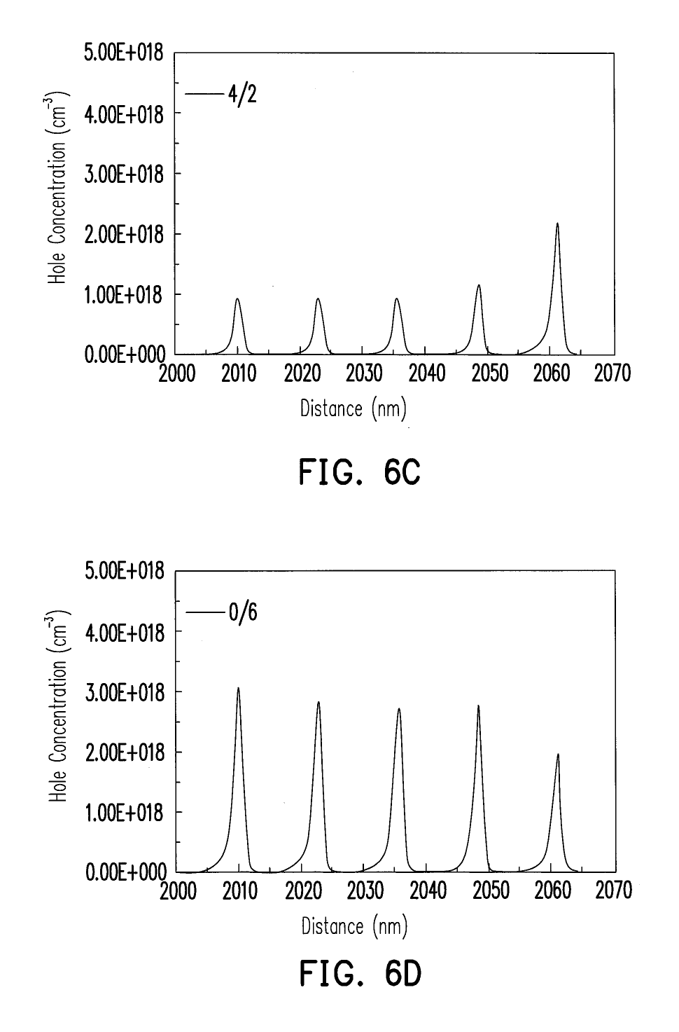

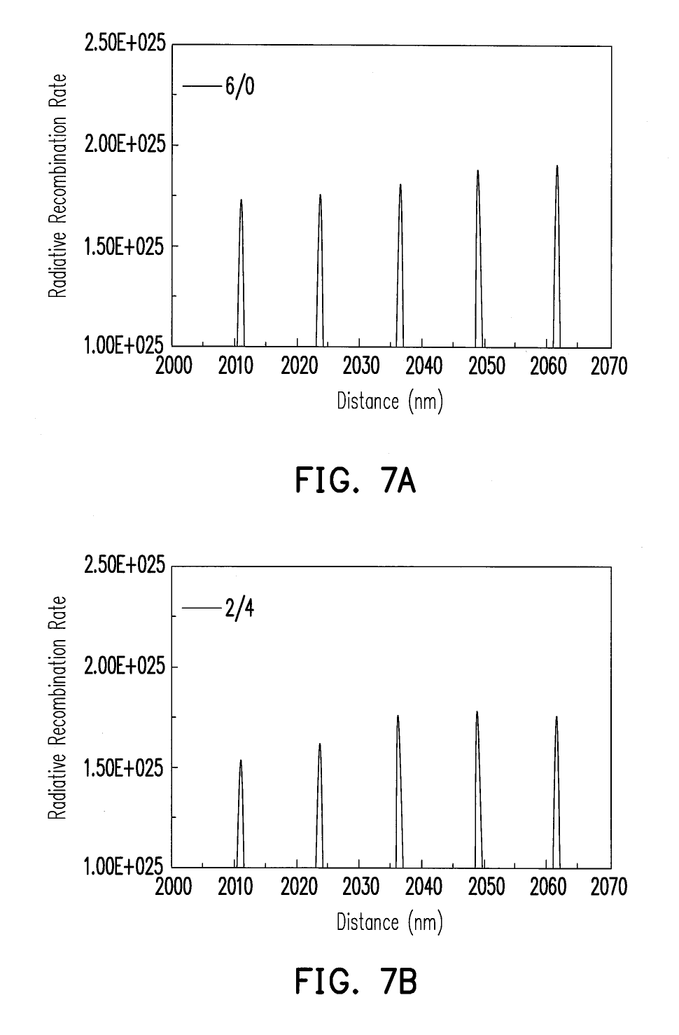

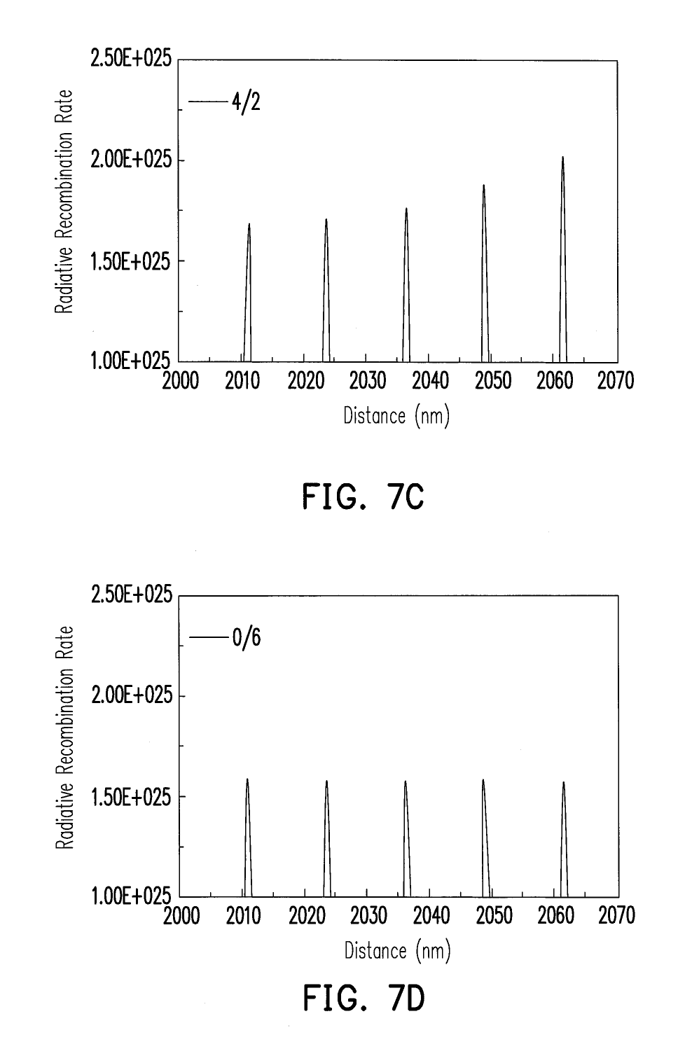

As shown by the electron concentration simulation diagrams from FIGS. 5A-5D, when the layer number of the doped quantum barrier layers increases, the electron concentration thereof gradually increases. As shown by the hole concentration simulation diagrams from FIGS. 6A-6D, when the layer number of the doped quantum barrier layers increases, the hole concentration thereof gradually decreases. Moreover, the overall hole concentration is highest when all of the quantum barrier layers are un-doped. As shown from the simulation diagrams of the electron-hole recombination rate in FIGS. 7A-7D, although the overall hole distribution is more even when all of the quantum barrier layers are doped, theoretically the electron-hole recombination rate in FIG. 7D for the LED having all un-doped quantum barrier layers should comparatively high. However, as shown by the trend in FIGS. 7A-7D, the highest electron-hole recombination rate occurs in FIG. 7A when all of the quantum barrier layers 232 are doped, and conversely, the lowest electron-hole recombination rate occurs when all of the quantum barrier layers 232 are un-doped. Therefore, FIGS. 7A-7D can also verify that n-type dopants can provide radiative recombination for electrons, and accordingly it can be deduced that the luminous efficiency of the LED with emission wavelength range of 222 nm-405 nm is effectively enhanced. Moreover, as shown by the simulation diagrams of the electron-hole non-radiative recombination rate in FIGS. 8A-8D, the lowest non-radiative recombination rate occurs in FIG. 8A when all of the quantum barrier layers are doped, and the highest electron-hole non-radiative recombination rate occurs in FIG. 8D when all of the quantum barrier layers are un-doped. Combining the results from FIGS. 7A-7D and FIGS. 8A-8D, doping the quantum barrier layers with n-type dopants can provide electrons to increase the electron-hole radiative recombination rate, thereby effectively enhancing the luminous efficiency. At the same time, the non-radiative recombination rate of electrons and holes which results in non-light emitting states such as heat is lowered, and this can also verify the deduced result that the n-type dopants are capable of enhancing the emission intensity of the LED at the 222 nm-405 nm emission wavelength range.

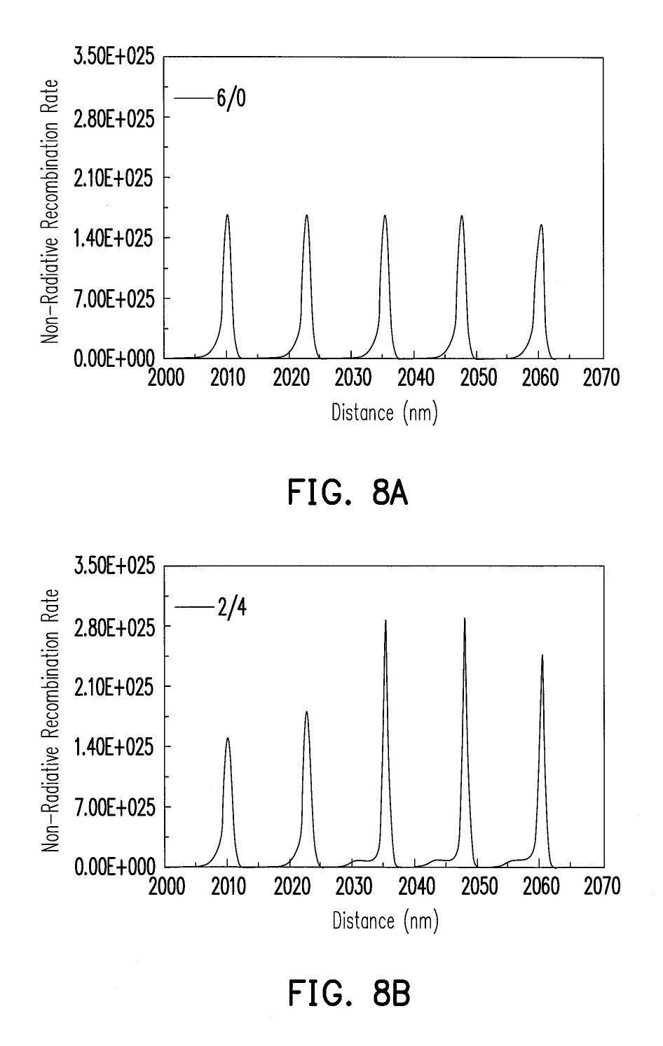

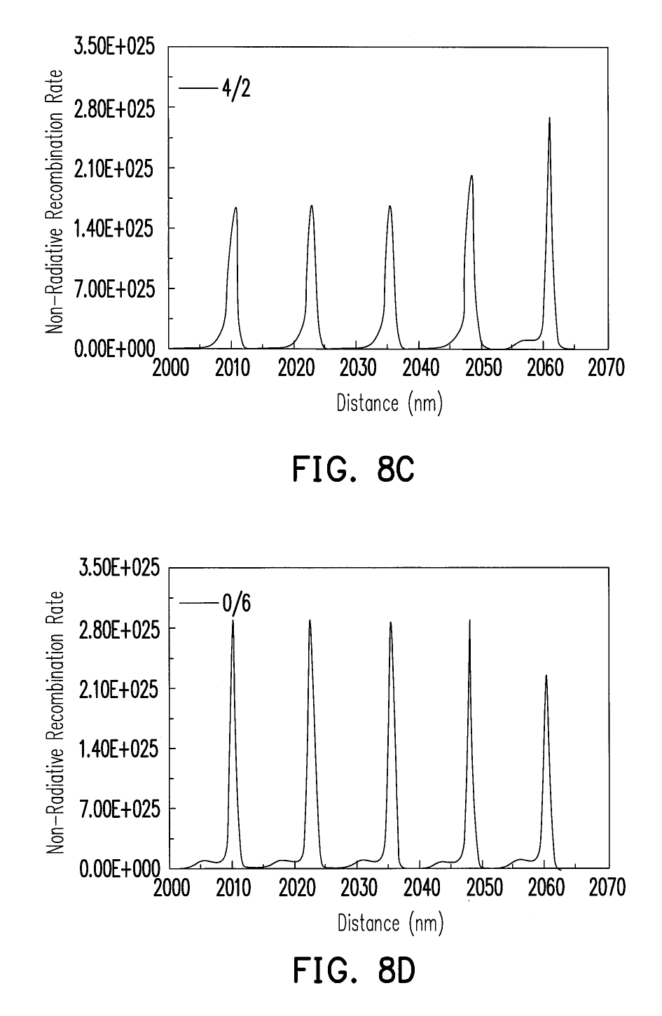

Table 1 records the emission intensity results under different currents of the LED having the active layer structure shown in FIG. 3. Table 1 also records the forward voltages which change with the layer numbers of the doped quantum barrier layers and the un-doped quantum barrier layers. In the experiments tabulated in FIG. 1, the doping concentrations C₁, C₂, . . . Cₖ are all 2×10¹⁸/cm³, for example. Moreover, in an embodiment where the emission wavelength is 365 nm, a material of the quantum wells is In_{c}Ga_{1-c}N, in which 0≦c≦0.05, and a material of the quantum barrier layers is Al_{d}Ga_{1-d}N, where d is between 0.13 to 0.30. In the present embodiment, a preferable aluminum concentration is 0.16-0.25, and a thickness of the quantum barrier layer is, for example, 5 nm-15 nm. The preferable thickness is 8 nm-12 nm in the present embodiment. Additionally, the results of Table 1 are illustrated in FIGS. 9A and 9B. FIG. 9A is a relational diagram depicting the impact different number of doped layers in the quantum barrier layers of an LED has on the current-output power curve. FIG. 9B is a relational diagram depicting the impact different number of doped layers in the quantum barrier layers of an LED has on the current-voltage curve.

TABLE 1

| | Total Quantum Barrier | | | | | Forward |
|---|---|---|---|---|---|---|
| | (QB) Layers i = 6 | | | Output Power | | Voltage |
| | Doped | | Doped | (mW) | | (V) |
| LED | QB | Un-Doped | Concen- | at | at | at |
| 200 | Layers k | QB Layers | tration | 350 mA | 700 mA | 350 mA |
| A | 0 | 6 | N.A. | 9.5 | 23.2 | 4.36 |
| B | 2 | 4 | 2 × 10¹⁸ | 10.6 | 24.9 | 4.29 |
| C | 4 | 2 | | 17.0 | 36.3 | 4.27 |
| D | 5 | 1 | | 24.2 | 49.0 | 4.13 |
| E | 6 | 0 | | 31.1 | 58.4 | 4.14 |

As shown in the results of Table 1 and FIG. 9A, the output powers of the LEDs 200A-200E increase as the number of doped quantum barrier layers grow in the quantum barrier layers available. To be specific, firstly, when the quantum barrier layers are not doped with n-type dopants, the doping concentration thereof is 0, but the GaN material has a background doping concentration that is different according to different epitaxial techniques or different epitaxy quality. In the present embodiment, since the background doping concentration cannot be measured, therefore the un-doped concentration is represented by N.A. At this time when six layers of quantum barrier layers are all un-doped with n-type dopants (e.g. Si), the output power is 9.5 mW (LED 200A). When two layers in the six layers of quantum barrier layers are doped with n-type dopants (e.g., purposely doping the two quantum barrier layers 232a-232b in the quantum barrier layer 232a-232f depicted in FIG. 3 closest to the n-type semiconductor layer 220), the output power of the LED 200B can be increased from the un-doped 9.5 mW to 10.6 mW. Preferably, when there are four doped quantum barrier layers 232 in the six quantum barrier layers 232 (e.g. purposely doping the four quantum barrier layers 232a-232d depicted in FIG. 3 closest to the n-type semiconductor layer 220), the output power of the LED 200C can be drastically increased from the un-doped 9.5 mW to 17.0 mW, which is a twofold enhancement. Therefore, when the layer number k of the doped quantum barrier layers 232 is greater than or equal to half of the total number of quantum barrier layers 232, the luminous efficiency of the LED 200C can be effectively increased. Moreover, when five of the quantum barrier layers are doped, the output power of the LED 200D is 24.2 mW. When all of the quantum barrier layers 232 are doped (e.g., purposely doping all six quantum barrier layers 232a-232f in FIG. 3), the output power of the LED 200E can be increased to 31.1 mW, which is close to a threefold enhancement.

Furthermore, as shown by the results of Table 1 and FIG. 9B, by doping n-type dopants in the quantum barrier layers, besides effectively increasing the luminous efficiency of the LED 200A, the resistance value of the quantum barrier layers can be further lowered, thereby reducing the forward voltage of the LED. For example, a forward voltage of 4.36 V when all of the quantum barrier layers are un-doped is lowered to 4.14V when all of the quantum barrier layers are doped. The foregoing results represent that by increasing the number of doped layers in the quantum barrier layers, the effect defect density has on the luminous efficiency of the LED at the 222 nm-405 nm wavelength range (main peak at around 365 nm) can be compensated. In other words, the n-type dopants injected in the quantum barrier layers can effectively provide electrons for radiative recombination, and lower energy release from non-radiative recombination such as heat. Accordingly, the luminous efficiency can be effectively enhanced, and the foregoing experimental results have verified the simulation results shown in FIGS. 5-8.

Therefore, in light of the above, the LED in the disclosure has a number of quantum barrier layers of the active layer doped with n-type dopants, in which the layer number of the doped quantum barrier layers satisfies a specific proportion, and accordingly the luminous efficiency of the LED at the 222 nm-405 nm wavelength range is effectively enhanced. When the layer number k of the doped quantum barrier layers is greater than or equal to half of the total number i of quantum barrier layers, the luminous efficiency enhancement effect is specifically pronounced. Specifically, when i is an even number, k≧i/2; and when i is an odd number, k≧(i−1)/2.

In the disclosure below, the effect that the doping concentration of the n-type dopant in the quantum barrier layers has on the luminous efficiency of the LED at the 222 nm-405 nm wavelength range is further discussed.

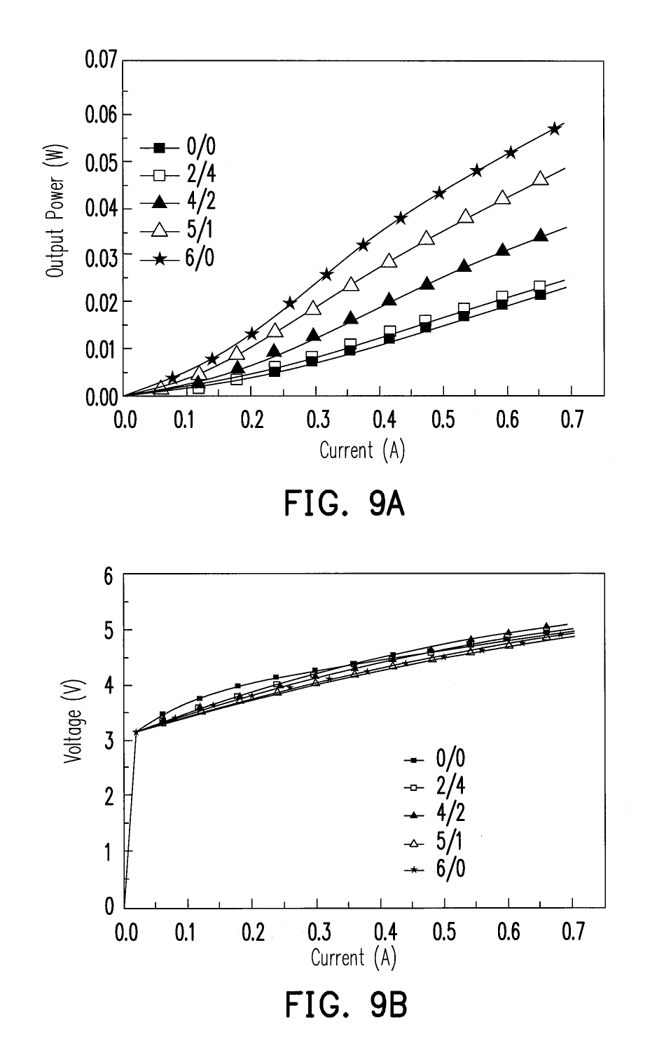

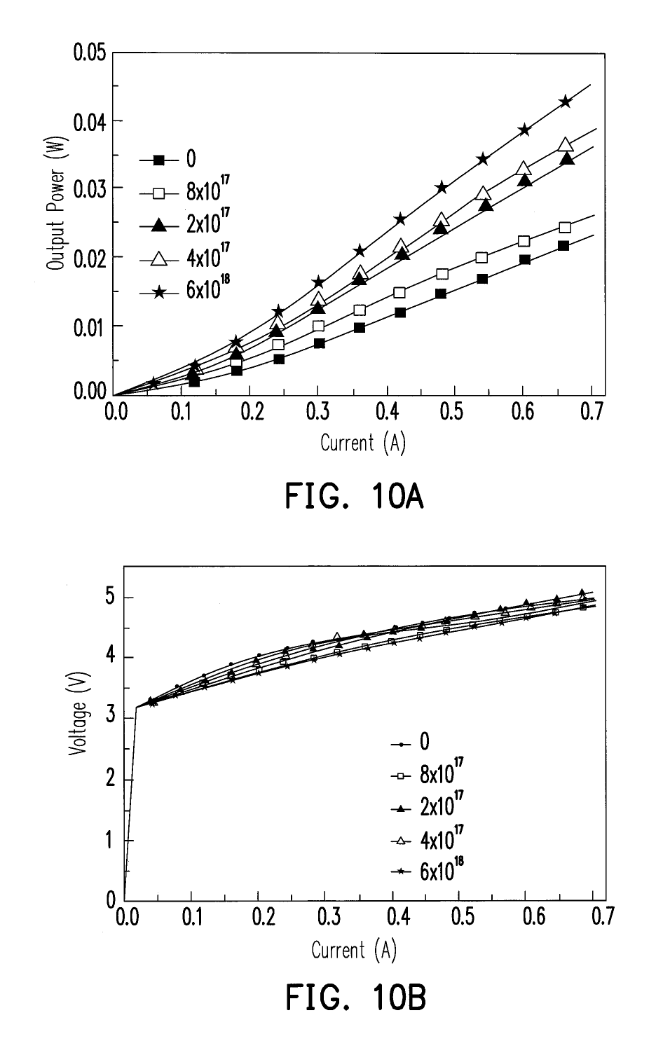

Table 2 records experiments of an LED having the active layer structure as depicted in FIG. 3, and the four quantum barrier layers 232a-232d closest to the n-type semiconductor layer are fixedly doped. Therefore, the number of doped quantum barrier layers 232 in each experiment of Table 2 is four layers, and the quantum barrier layers 232e-232f closest to the p-type semiconductor layer are un-doped. Table 2 represents the impact different doping concentrations in the doped quantum barrier layers of the LED has on the emission intensity and the forward voltage performance. Additionally, the results of Table 2 are illustrated in FIGS. 10A and 10B. FIG. 10A is a relational diagram depicting the impact different doping concentrations in the quantum barrier layers of an LED has on the current-output power curve. FIG. 10B is a relational diagram depicting the impact different doping concentrations in the quantum barrier layers of an LED has on the current-voltage curve.

TABLE 2

| | Total QB Layers | | | | | |
|---|---|---|---|---|---|---|
| | 232 i = 6 | | | | | Forward |
| | | | Doping | Output Power | | Voltage |
| | Doped | | Concen- | (mW) | | (V) |
| LED | QB | Un-Doped | tration | at | at | at |
| 200 | Layers k | QB Layers | (cm⁻³) | 350 mA | 700 mA | 350 mA |
| A | 0 | 6 | N.A. | 9.5 | 23.2 | 4.36 |
| F | 4 | 2 | ~8 × 10¹⁷ | 11.8 | 26.1 | 4.14 |
| G | | | ~2 × 10¹⁸ | 17.0 | 36.3 | 4.27 |
| H | | | ~4 × 10¹⁸ | 19.1 | 38.9 | 4.14 |
| I | | | ~6 × 10¹⁸ | 21.5 | 45.3 | 4.09 |

As shown in the results of Table 2 and FIG. 10A and by referring to FIG. 3, the output powers of the LED increases as the doping concentration grows. For example, as described earlier, when no n-type dopants are doped, since the background doping concentration cannot be measured, therefore the un-doped concentration is represented by N.A, and the output power thereof is 9.5 mW (LED 200A). When the doping concentration of four doped quantum barrier layers 232a-232d is 8×10¹⁷ cm⁻³, the output power of the LED 200F is increased from the un-doped 9.5 mW to 11.8 mW. Preferably, when the doping concentration is 2×10¹⁸ cm⁻³, the output power of the LED 200G can be drastically increased from the un-doped 9.5 mW to 17.0 mW, which is a twofold enhancement. Moreover, when the doping concentration is 4×10¹⁸ cm⁻³, the output power of the LED 200H is 19.1 mW, and when the doping concentration is 6×10¹⁸ cm⁻³, the output power of the LED 200E can be enhanced to 21.5 mW. Therefore, it can deduced from Table 2 and FIG. 10A that in the quantum barrier layers of the LED, when the number of doped layers is over half of the total layers, and the doping concentration is 5×10¹⁷/cm³ to 1×10¹⁹/cm³, the luminous efficiencies of the LEDs 200E-2001 can be effectively enhanced.

Moreover, as shown by the results of Table 2 and FIG. 10B, when the doping concentration in the four doped quantum barrier layers is between 5×10¹⁷/cm³ to 1×10¹⁹/cm³, besides effectively increasing the luminous efficiency of the LED, the n-type dopants can also lower the resistance value of the quantum barrier layers, thereby reducing the forward voltage of the LED. For example, the forward voltage of the LED is reduced from 4.36 V when the doping concentration is 0 to 4.09 V when the doping concentration is 6×10¹⁸/cm³. The foregoing results represent that by increasing the doping concentration of the n-type dopants (e.g. Si) in the quantum barrier layers 232, the effect defect density has on the luminous efficiency of the LED at the 222 nm-405 nm wavelength range can be effectively compensated. In other words, the n-type dopants injected in the quantum barrier layers can effectively provide electrons for radiative recombination, and lower energy release from non-radiative recombination such as heat. Accordingly, the luminous efficiency can be effectively enhanced, and the foregoing experimental results have verified the simulation results shown in FIGS. 5-8.

It should be noted that, according to the embodiments of the LEDs 200B-2001 in the disclosure, at least one element in the group IVA may also be used as the n-type dopant to provide electrons for radiative recombination, and thereby enhance the luminous efficiency. Moreover, besides the doping concentrations in the doped quantum barrier layers being equal to the values tabulated in Table 1 and 2, the doping concentrations may also have a laddered variation. As an example, the total number of quantum barrier layers is six, and four of the six layers are doped quantum barrier layers. The doping concentrations of the four doped quantum barrier layers are C₁, C₂, . . . Cₖ, where Cₖ≦Cₖ₋₁, counting sequentially from the n-type semiconductor side. For example, the doping concentrations of the four doped quantum barrier layers 232a-232d are 6×10¹⁸ cm⁻³, 5×10¹⁸ cm⁻³, 4×10¹⁸ cm⁻³, and 3×10¹⁸ cm⁻³ in sequence. In other words, the doping concentrations of the doped quantum barrier layers vary by gradually decreasing from the first quantum barrier layer 232a closest to the n-type semiconductor side to the fourth layer 232d closest to the p-type semiconductor side. Accordingly, the n-type dopants injected can also effectively provide electrons for radiative recombination, and thereby enhance the luminous efficiency.

Additionally, the laddered variation of the doping concentrations C₁ to Cₖ in the doped quantum barrier layers may also be 6×10¹⁸ cm⁻³, 7×10¹⁸ cm⁻³, 8×10¹⁸ cm⁻³, and 6×10¹⁸ cm⁻³ in sequence counting from the n-type semiconductor side. In other words, the variation of the doping concentrations may be in a state where the doping concentrations of the middle layers are greater than the doping concentrations of the layers nearest to the n-type semiconductor and the p-type semiconductor. Moreover, the laddered variation of the doping concentrations in the doped quantum barrier layers may also be 6×10¹⁸ cm⁻³, 5×10¹⁸ cm⁻³, 8×10¹⁸cm⁻³, and 6×10¹⁸ cm⁻³ in sequence counting from the n-type semiconductor side. To sum up, as long as the doping concentration of the doped quantum barrier layer nearest to the p-type semiconductor layer is less than or equal to the doping concentrations of the other quantum barrier layers in the k doped quantum barrier layers, the injected n-type dopants can effectively provide electrons for radiative recombination, and thereby enhance the luminous efficiency.

In view of the foregoing, in the LED according to the embodiments of the disclosure, by having a number of quantum barrier layers of the active layer doped with n-type dopants, in which the layer number of the doped quantum barrier layers satisfies a specific relationship, or by having the lowest doping concentration at the quantum barrier layer doped with n-type dopants that is closest to the p-type semiconductor, or by having the doping concentrations of the quantum barrier layers doped with n-type dopants satisfying a specific relationship, the n-type dopants can compensate for the effect which defects of GaN have on the carriers. Accordingly, the carrier recombination rate of the LED can be enhanced. Therefore, by employing any one of the afore-described techniques, the luminous efficiency of the LED in the disclosure can be drastically increased at the 222 nm-405 nm wavelength range.

Moreover, the LED of the disclosure is not limited to the embodiments depicted above. The LED may be configured with horizontal electrodes or vertical electrodes, both of which can implement the disclosure but should not be construed as limiting the disclosure.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A light emitting diode, comprising:
a substrate;
a n-type semiconductor layer disposed on the substrate;
an active layer having a defect density DD, wherein DD≧2×10⁷/cm³, the active layer is disposed on a portion of the n-type semiconductor layer, and a wavelength λ, of light emitted by the active layer is 222 nm≦λ≦405 nm, the active layer comprising i quantum barrier layers and (i−1) quantum wells, each of the quantum wells is disposed between any two quantum barrier layers, and i is a natural number greater than or equal to 2, wherein a n-type dopant is doped in at least k layers of the quantum barrier layers, k being a natural number greater than or equal to 1, when i is an even number, k≧i/2, and when i is an odd number, k≧(i−1)/2;
a p-type semiconductor layer disposed on the active layer; and
a first electrode and a second electrode, wherein the first electrode is disposed on a portion of the n-type semiconductor layer, and the second electrode is disposed on a portion of the p-type semiconductor layer.

2. The light emitting diode as claimed in claim 1, wherein the k quantum barrier layers doped with the n-type dopant are located nearest to the n-type semiconductor layer.

3. The light emitting diode as claimed in claim 1, wherein a material of the quantum barrier layers comprises AlₓIn_{y}Ga_{1-x-y}N, wherein 0≦x≦1, 0≦y≦0.3, and x+y≦1.

4. The light emitting diode as claimed in claim 1, wherein a thickness of each of the quantum barrier layers is between 5 nm to 15 nm.

5. The light emitting diode as claimed in claim 1, wherein a material of the quantum barrier layers comprises AlₘInₙGa₁₋ₘ₋ₙN, wherein 0≦m<1, 0≦n≦0.5, m+n≦1, x>m, and n≧y.

6. A light emitting diode, comprising:
a substrate;
a n-type semiconductor layer disposed on the substrate;
an active layer having a defect density DD, wherein DD≧2×10⁷/cm³, the active layer is disposed on a portion of the n-type semiconductor layer, and a wavelength λ of light emitted by the active layer is 222 nm≦λ≦405 nm, the active layer comprising i quantum barrier layers and (i−1) quantum wells, each of the quantum wells is disposed between any two quantum barrier layers, and i is a natural number greater than or equal to 2, wherein a n-type dopant is doped in at least k layers of the quantum barrier layers, k being a natural number greater than or equal to 1, when i is an even number, k≧i/2, and when i is an odd number, k≧(i−1)/2;
a p-type semiconductor layer disposed on the active layer, a doping concentration of the quantum barrier layer in the k quantum barrier layers nearest to the p-type semiconductor layer being less than or equal to the doping concentration of the other quantum barrier layers in the k quantum barrier layers; and
a first electrode and a second electrode, wherein the first electrode is disposed on a portion of the n-type semiconductor layer, and the second electrode is disposed on a portion of the p-type semiconductor layer.

7. The light emitting diode as claimed in claim 6, wherein the k quantum barrier layers doped with the n-type dopant are located nearest to the n-type semiconductor layer.

8. The light emitting diode as claimed in claim 7, wherein the doping concentration of the k quantum barrier layers is at least 5×10¹⁷/cm³.

9. The light emitting diode as claimed in claim 7, wherein the doping concentration of the each of the k quantum barrier layers counting sequentially from the n-type to the p-type semiconductor layer side are C₁, C₂, . . . Cₖ, where Cₖ≦Cₖ₋₁.

10. The light emitting diode as claimed in claim 6, wherein a material of the quantum barrier layers comprises AlₓIn_{y}Ga_{1-x-y}N, wherein 0≦x≦1, 0≦y≦0.3, and x+y≦1.

11. The light emitting diode as claimed in claim 6, wherein a thickness of each of the quantum barrier layers is between 5 nm to 15 nm.

12. The light emitting diode as claimed in claim 6, wherein a material of the quantum barrier layers comprises AlₘInₙGa₁₋ₘ₋ₙN, wherein 0≦m<1, 0≦n≦0.5, m+n≦1, x>m, and n≧y.

13. A light emitting diode, comprising:
a substrate;
a n-type semiconductor layer disposed on the substrate;
an active layer having a defect density DD, wherein DD≧2×10⁷/cm³, the active layer is disposed on a portion of the n-type semiconductor layer, and a wavelength λ of light emitted by the active layer is 222 nm≦λ≦405 nm, the active layer comprising i quantum barrier layers and (i−1) quantum wells, each of the quantum wells is disposed between any two quantum barrier layers, and i is a natural number greater than or equal to 2, wherein a n-type dopant is doped in at least k layers of the quantum barrier layers, k being a natural number greater than or equal to 1, when i is an even number, k≧i/2, when i is an odd number, k≧(i−1)/2, and a doping concentration of the k quantum barrier layers is from 5×10¹⁷/cm³ to 1×10¹⁹/cm³;
a p-type semiconductor layer disposed on the active layer; and
a first electrode and a second electrode, wherein the first electrode is disposed on a portion of the n-type semiconductor layer, and the second electrode is disposed on a portion of the p-type semiconductor layer.

14. The light emitting diode as claimed in claim 13, wherein the k quantum barrier layers doped with the n-type dopant are located nearest to the n-type semiconductor layer.

15. The light emitting diode as claimed in claim 13, wherein the doping concentration of the quantum barrier layer in the k quantum barrier layers nearest to the p-type semiconductor layer is less than or equal to the doping concentration of the other quantum barrier layers in the k quantum barrier layers.

16. The light emitting diode as claimed in claim 13, wherein a thickness of each of the quantum barrier layers is between 5 nm to 15 nm.
